(19) United States
(12) Patent Application Publication
(10) Pub. No.: US 2025/0096739 A1
(43) Pub. Date: Mar. 20, 2025

(54) POWER AMPLIFIER

(71) Applicant: Murata Manufacturing Co., Ltd., Kyoto (JP)

(72) Inventor: Yuri HONDA, Kyoto (JP)

(21) Appl. No.: 18/830,720

(22) Filed: Sep. 11, 2024

(30) Foreign Application Priority Data
Sep. 15, 2023 (JP) 2023-150197

(51) Int. Cl. H03F 1/52; H03F 3/24

(52) U.S. Cl. CPC H03F 1/52; H03F 3/245; H03F 2200/426; H03F 2200/451

(57) ABSTRACT

A power amplifier, which includes a plurality of stages of amplification units each of which includes a common-emitter transistor, includes a first amplification unit including a first transistor configured to amplify an input radio-frequency signal, a second amplification unit including a second transistor configured to amplify an output of the first amplification unit, a voltage detection circuit including at least one impedance element and provided between the first transistor and the second transistor, and a protection circuit configured to reduce, based on an output of the voltage detection circuit, a base bias current applied to at least one of the first transistor and the second transistor.

### CROSS REFERENCE TO RELATED APPLICATION

This application claims priority from Japanese Patent Application No. 2023-150197 filed on Sep. 15, 2023. The content of this application is incorporated herein by reference in its entirety.

### BACKGROUND OF THE DISCLOSURE

### 1. Field of the Disclosure

The present disclosure relates to a power amplifier.

### 2. Description of the Related Art

A radio-frequency power amplifier, which connects a plurality of amplification stages to each other by using transistors to amplify a radio-frequency signal, is known. A power amplifier disclosed in Japanese Patent No. 4685836 includes a protection circuit connected to an output of an amplification stage. The protection circuit is turned on at the timing when reaching a certain or more voltage amplitude, and a base current of a transistor constituting the previous amplification stage is drawn. Thereby, the protection circuit protects the transistor from being destroyed.

### BRIEF SUMMARY OF THE DISCLOSURE

However, when an amplitude of a radio-frequency signal is large and an on-state and an off-state of a protection circuit are repeated, there may be a case where the power amplifier described above cannot suppress the destruction of a transistor.

The present disclosure is made in view of the above description, and an object of the present disclosure is to provide a power amplifier capable of suppressing destruction of a transistor even when an amplitude of a radio-frequency signal is large.

In order to solve the above-described problem and achieve the object, a power amplifier according to an aspect of the present disclosure is a power amplifier including a plurality of stages of amplification units each of which includes a common-emitter transistor, and includes a first amplification unit including a first transistor configured to amplify an input radio-frequency signal, a second amplification unit including a second transistor configured to amplify an output of the first amplification unit, a voltage detection circuit including at least one impedance element and provided between the first transistor and the second transistor, and a protection circuit configured to reduce, based on an output of the voltage detection circuit, a base bias current applied to at least one of the first transistor and the second transistor.

According to the present disclosure, it is possible to suppress the destruction of a transistor even when an amplitude of a radio-frequency signal is large.

### BRIEF DESCRIPTION OF THE SEVERAL VIEWS OF THE DRAWINGS

FIG. 1 is a diagram illustrating a power amplifier of a comparative example;

FIG. 2 is a diagram illustrating a power amplifier according to a first embodiment of the present disclosure;

FIG. 3 is a diagram illustrating an operation example of a voltage detection circuit;

FIG. 4 is a diagram illustrating an example of a state in which a waveform is distorted;

FIG. 5 is a diagram illustrating a relationship among a detection voltage outputted from a voltage detection circuit, a current drawn by a protection circuit, and a collector current of each transistor;

FIG. 6 is a diagram illustrating a relationship between a voltage level of an input radio-frequency signal and a collector current;

FIG. 7 is a diagram illustrating a voltage detection circuit used for the power amplifier illustrated in FIG. 2;

FIG. 8 is a diagram illustrating a modification example of the voltage detection circuit;

FIG. 9 is a diagram illustrating a modification example of the voltage detection circuit;

FIG. 10 is a diagram illustrating a modification example of the voltage detection circuit;

FIG. 11 is a diagram illustrating a first example of a level shift circuit and a protection circuit;

FIG. 12 is a waveform diagram illustrating operations of the level shift circuit and the protection circuit illustrated in FIG. 11;

FIG. 13 is a diagram illustrating a second example of the level shift circuit and the protection circuit;

FIG. 14 is a waveform diagram illustrating operations of the level shift circuit and the protection circuit illustrated in FIG. 13;

FIG. 15 is a diagram illustrating a third example of the level shift circuit and the protection circuit;

FIG. 16 is a waveform diagram illustrating operations of the level shift circuit and the protection circuit illustrated in FIG. 15;

FIG. 17 is a diagram illustrating a fourth example of the level shift circuit and the protection circuit;

FIG. 18 is a waveform diagram illustrating operations of the level shift circuit and the protection circuit illustrated in FIG. 17;

FIG. 19 is a diagram illustrating a fifth example of the level shift circuit and the protection circuit;

FIG. 20 is a waveform diagram illustrating operations of the level shift circuit and the protection circuit illustrated in FIG. 19;

FIG. 21 is a diagram illustrating a sixth example of the level shift circuit and the protection circuit;

FIG. 22 is a waveform diagram illustrating operations of the level shift circuit and the protection circuit illustrated in FIG. 21;

FIG. 23 is a diagram illustrating a first example in which the level shift circuit is combined with the protection circuit;

FIG. 24 is a diagram illustrating a second example in which the level shift circuit is combined with the protection circuit;

FIG. 25 is a diagram illustrating a power amplifier according to a second embodiment of the present disclosure;

FIG. 26 is a diagram illustrating a power amplifier according to a third embodiment of the present disclosure;

FIG. 27 is a diagram illustrating an example of a layout when the power amplifier of the present disclosure is realized on a substrate;

FIG. 28 is a diagram illustrating an example of a layout when the power amplifier of the present disclosure is realized on a substrate; and

FIG. 29 is a diagram illustrating an example of a layout when the power amplifier of the present disclosure is realized on a substrate.

### DETAILED DESCRIPTION OF THE DISCLOSURE

Hereinafter, embodiments of the present disclosure will be described in detail with reference to the drawings. In describing each of the following embodiments, the same components as or components equivalent to the components in other embodiments will be designated by the same reference numerals, and descriptions thereof are simplified or omitted. The present disclosure is not limited to respective embodiments. In addition, components of the respective embodiments include components that can be substituted and easily substituted by those skilled in the art, or substantially the same components. The configurations described below can be appropriately combined with each other. In addition, the configurations can be omitted, replaced, or changed without departing from the gist of the disclosure.

### First Embodiment

Hereinafter, a first embodiment will be described, but a comparative example will be described first to facilitate understanding of the first embodiment.

### Configuration of Comparative Example

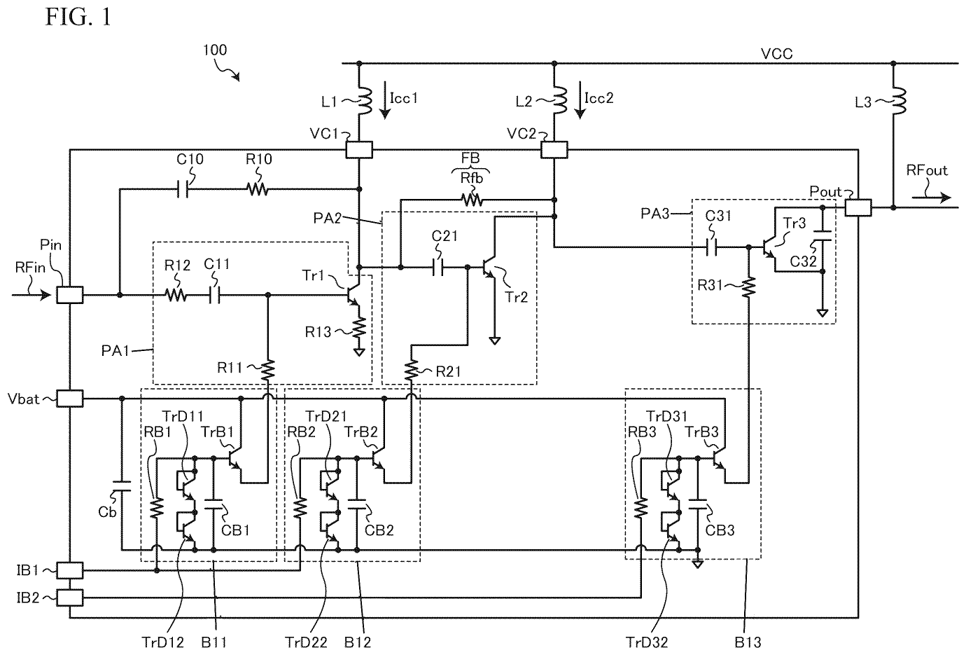

FIG. 1 is a diagram illustrating a power amplifier 100 of a comparative example. In FIG. 1, the power amplifier 100 is a three-stage amplifier and includes amplification units PA1, PA2, and PA3. That is, the power amplifier 100 includes a first stage amplification unit PA1, a second stage amplification unit PA2, and a third stage amplification unit PA3. The amplification units PA1, PA2, and PA3 amplify an input radio-frequency signal and sequentially output the amplified signal to subsequent stages. The amplification unit PA1 corresponds to a first amplification unit of the present disclosure. The amplification unit PA2 corresponds to a second amplification unit of the present disclosure. The amplification unit PA3 corresponds to a third amplification unit of the present disclosure.

Each of the amplification units PA1, PA2, and PA3 includes a common-emitter transistor. The amplification unit PA1 includes a common-emitter transistor Tr1, a capacitor C11 connected to a base of the transistor Tr1, and resistors R11, R12, and R13. A bias current to be described below is provided to a base of the transistor Tr1 through the resistor R11. An emitter of the transistor Tr1 is connected to a reference potential through the resistor R13. The reference potential is, for example a ground potential, but the present disclosure is not limited thereto. The same applies to the following description. A signal amplified by the amplification unit PA1 is outputted from a collector of the transistor Tr1. A capacitor C10 and a resistor R10 are connected in series to each other between an input and an output of the amplification unit PA1. The transistor Tr1 corresponds to a first transistor of the present disclosure.

The amplification unit PA2 includes a common-emitter transistor Tr2, a capacitor C21 connected to a base of the transistor Tr2, and a resistor R21. A bias current to be described below is provided to a base of the transistor Tr2 through the resistor R21. An emitter of the transistor Tr2 is connected to the reference potential. A signal amplified by the amplification unit PA2 is outputted from a collector of the transistor Tr2. The transistor Tr2 corresponds to a second transistor of the present disclosure.

The amplification unit PA3 includes a common-emitter transistor Tr3, a capacitor C31 connected to a base of the transistor Tr3, a capacitor C32 connected between a collector and an emitter of the transistor Tr3, and a resistor R31. A bias current to be described below is provided to a base of the transistor Tr3 through the resistor R31. The emitter of the transistor Tr3 is connected to the reference potential. A signal amplified by the amplification unit PA3 is outputted from the collector of the transistor Tr3.

In the present disclosure, a transistor is a bipolar transistor, but the present disclosure is not limited thereto. The bipolar transistor is, for example, a heterojunction bipolar transistor (HBT), but the present disclosure is not limited thereto. The transistor may be, for example, a field effect transistor (FET). In this case, a collector, a base, and an emitter may be read respectively as a drain, a gate, and a source. The transistor may be a multi-finger transistor in which a plurality of unit transistors (also referred to as fingers) are electrically connected in parallel to each other. The unit transistor refers to a minimum configuration for configuring the transistor.

The power amplifier 100 includes an input terminal Pin, an output terminal Pout, power supply terminals VC1, VC2, and Vbat, and bias input terminals IB1 and IB2. A radio-frequency signal RFin is inputted to the input terminal Pin. The output terminal Pout outputs a radio-frequency signal RFout.

The power amplifier 100 includes choke coils L1, L2, and L3. One end of each of the choke coils L1, L2, and L3 is connected to a power supply VCC. The other end of the choke coil L1 is connected to the power supply terminal VC1. The other end of the choke coil L2 is connected to the power supply terminal VC2. The other end of the choke coil L3 is connected to the output terminal Pout.

The power supply terminal VC1 is connected to the power supply VCC through the choke coil L1. A current flowing from the power supply VCC to the collector of the transistor Tr1 of the amplification unit PA1 is defined as a current Icc1. The power supply terminal VC2 is connected to the power supply VCC through the choke coil L2. A current flowing from the power supply VCC to the collector of the transistor Tr2 of the amplification unit PA2 is defined as a current Icc2. The output terminal Pout is connected to the power supply VCC through the choke coil L3.

In addition, the power amplifier 100 includes a bias circuit B11 provided to correspond to the amplification unit PA1, a bias circuit B12 provided to correspond to the amplification unit PA2, and a bias circuit B13 provided to correspond to the amplification unit PA3. The bias circuit B11 corresponds to a first bias circuit of the present disclosure. The bias circuit B12 corresponds to a second bias circuit of the present disclosure.

The bias circuit B11 includes a transistor TrB1, a resistor RB1, transistors TrD11 and TrD12, and a capacitor CB1. One end of the resistor RB1 is connected to a base of the transistor TrB1, and the other end of the resistor RB1 is connected to the bias input terminal IB1. Each of the transistors TrD11 and TrD12 has a base and a collector connected to each other and operates as a diode. One end of the capacitor CB1 is connected to the base of the transistor TrB1, and the other end of the capacitor CB1 is connected to the reference potential.

The bias circuit B12 includes a transistor TrB2, a resistor RB2, transistors TrD21 and TrD22, and a capacitor CB2. One end of the resistor RB2 is connected to a base of the transistor TrB2, and the other end of the resistor RB2 is connected to the bias input terminal IB1. Each of the transistors TrD21 and TrD22 has a base and a collector connected to each other and operates as a diode. One end of the capacitor CB2 is connected to the base of the transistor TrB2, and the other end of the capacitor CB2 is connected to the reference potential.

The bias circuit B13 includes a transistor TrB3, a resistor RB3, transistors TrD31 and TrD32, and a capacitor CB3. One end of the resistor RB3 is connected to a base of the transistor TrB3, and the other end of the resistor RB3 is connected to the bias input terminal IB2. Each of the transistors TrD31 and TrD32 has a base and a collector connected to each other and operates as a diode. One end of the capacitor CB3 is connected to the base of the transistor TrB3, and the other end of the capacitor CB3 is connected to the reference potential.

A capacitor Cb is connected between the power supply terminal Vbat for each of the bias circuits B11, B12, and B13 and the reference potential.

Here, the power amplifier 100 includes a feedback circuit FB for adjusting a gain. The feedback circuit FB is connected between the amplification unit PA1 and the amplification unit PA2. One end of the feedback circuit FB is connected to the collector of the transistor Tr1 of the amplification unit PA1. The other end of the feedback circuit FB is connected to the collector of the transistor Tr2 of the amplification unit PA2. The feedback circuit FB of the present example is a resistor Rfb that connects the collector of the transistor Tr1 to the collector of the transistor Tr2. A gain of the amplification unit PA2 can be adjusted by the feedback circuit FB.

### Operation of Comparative Example

The amplification unit PA1 amplifies the radio-frequency signal RFin which is an input signal to the input terminal Pin of the power amplifier 100. An output signal of the amplification unit PA1 is inputted to the amplification unit PA2. The amplification unit PA2 amplifies the output signal of the amplification unit PA1. An output signal of the amplification unit PA2 is inputted to the amplification unit PA3. The amplification unit PA3 amplifies the output signal of the amplification unit PA2 and outputs an amplified output signal from the output terminal Pout as the radio-frequency signal RFout.

### Power Amplifier According to First Embodiment

### Configuration

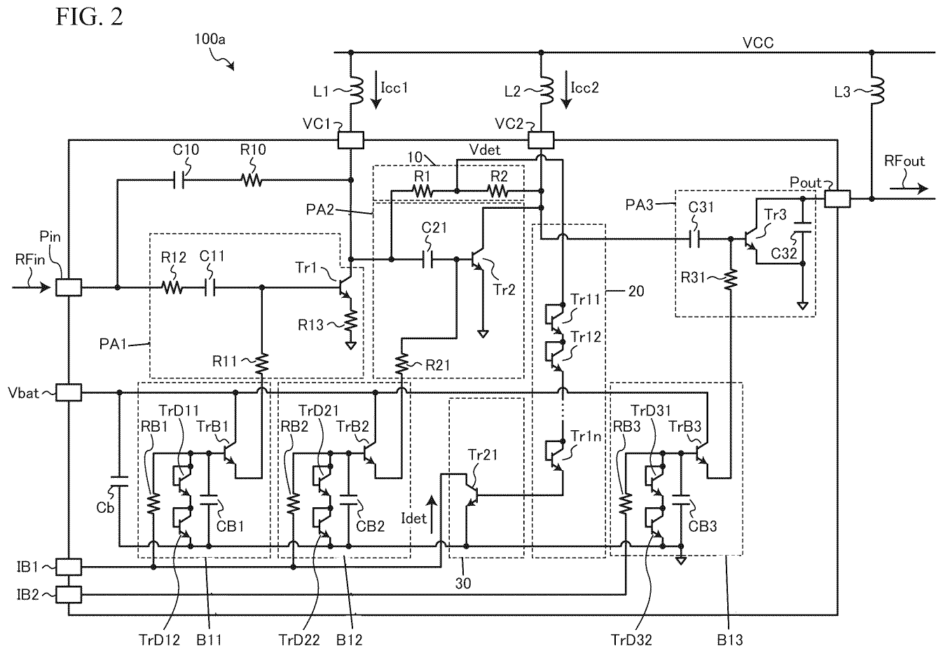

FIG. 2 is a diagram illustrating a power amplifier 100a according to a first embodiment of the present disclosure. In FIG. 2, the power amplifier 100a according to the first embodiment has a configuration in which a voltage detection circuit 10 is provided instead of the feedback circuit FB in the power amplifier 100 of the comparative example described with reference to FIG. 1, and a level shift circuit 20 and a protection circuit 30 are added to the power amplifier 100.

The voltage detection circuit 10 is provided instead of the feedback circuit FB in FIG. 1. The voltage detection circuit 10 is connected between the amplification unit PA1 and the amplification unit PA2. One end of the voltage detection circuit 10 is connected to a collector of a transistor Tr1 of an amplification unit PA1. The other end of the voltage detection circuit 10 is connected to a collector of a transistor Tr2 of an amplification unit PA2. The voltage detection circuit 10 in FIG. 2 has a configuration in which a resistor R1 which is a first resistor is connected in series to a resistor R2 which is a second resistor. A detection voltage Vdet, which is a direct-current voltage, is obtained from a node between the resistor R1 and the resistor R2. The resistors R1 and R2 connected in series correspond to impedance elements of the present disclosure. By using the resistors R1 and R2 which are impedance elements, a direct-current voltage is outputted. A configuration and modification example of the voltage detection circuit 10 will be described below.

The level shift circuit 20 includes n (n is a natural number, and the same applies hereinafter) transistors Tr11, Tr12, . . . , and Tr1n. A base and a collector of each of the n transistors are connected to each other, and each of the n transistors operates as a diode.

Therefore, a voltage drop in the pn junction is n times, and a voltage level decreases depending on the number of connected transistors. That is, the level shift circuit 20 can convert the level of a direct-current voltage outputted from the voltage detection circuit 10. A configuration and modification example of the level shift circuit 20 will be described below. Hereinafter, a circuit including at least one diode, such as at least one transistor that operates as a diode, will be referred to as a diode circuit.

The protection circuit 30 includes a transistor Tr21. The transistor Tr21 corresponds to a third transistor of the present disclosure. When the transistor Tr21 is turned on, a current Idet flows. When the current Idet flows, a current can be drawn from bias circuits B11 and B12 to reduce a bias current. A configuration and modification example of the protection circuit 30 will be described below.

### Operation

The transistor Tr2 of the amplification unit PA2 is a common-emitter. Accordingly, a phase difference between a signal of the collector of the transistor Tr1 and a signal of the collector of the transistor Tr2 is about 180°. A detection voltage Vdet, which is a direct-current voltage, is obtained by combining two signals having a phase difference of about 180° by using the voltage detection circuit 10.

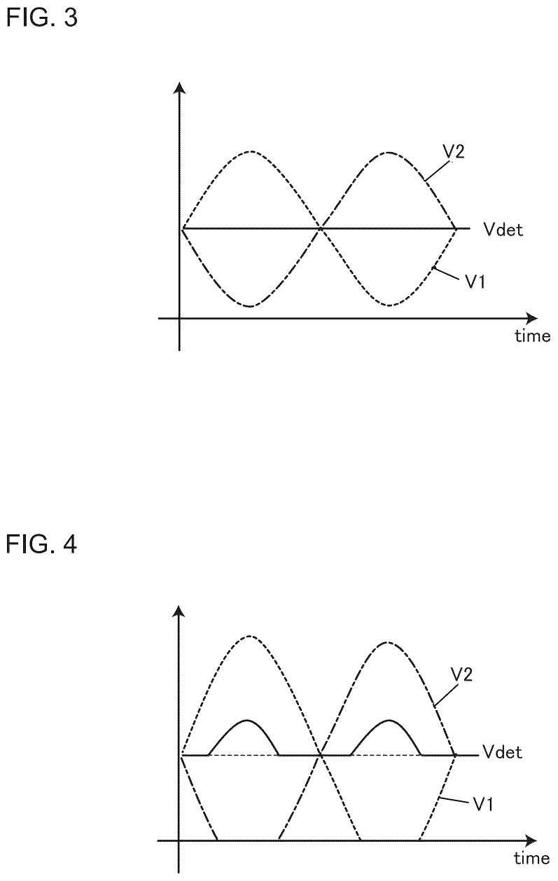

FIG. 3 is a diagram illustrating an operation example of the voltage detection circuit 10. In FIG. 3, a horizontal axis denotes the lapse of time, and a vertical axis denotes a voltage value. In FIG. 3, a phase of a voltage V1 appearing at the collector of the transistor Tr1 of the amplification unit PA1 is different from a phase of a voltage V2 appearing at the collector of the transistor Tr2 of the amplification unit PA2 by about 180°. Accordingly, the voltage detection circuit 10 outputs the detection voltage Vdet by combining the voltage V1 and the voltage V2. By operating the transistor Tr21 of the protection circuit 30 with the detection voltage Vdet, the current Idet flows, and currents are drawn from the bias circuits B11 and B12, and thus, the bias current can be reduced. That is, when the transistor Tr21, which is the third transistor, is turned on, the bias current provided to the transistor Tr1 from the bias circuit B11 and the bias current provided to the transistor Tr2 from the bias circuit B12 are reduced.

The power amplifier 100a includes choke coils L1 and L2 connected between a line of a power supply VCC and the collectors of the transistors Tr1 and Tr2 of the amplification units PA1 and PA2. Although a signal of the line of the power supply VCC is a direct current, an amplitude of the radio-frequency signal appears in the collectors of the transistors Tr1 and Tr2. When it is intended to obtain a direct-current voltage from the line of the power supply VCC to extract the direct-current voltage, wiring and an electrode pad for supplying power to a transistor need to be added, which is not preferable. Therefore, as described above, values of the resistors R1 and R2 connected between the two voltages V1 and V2 are set to cancel a radio-frequency amplitude appearing at the node therebetween. With this configuration, the two voltages V1 and V2 having phases of amplitudes different from each other by about 180° are combined with each other, and as illustrated in FIG. 3, it is possible to extract a substantially direct-current detection voltage Vdet.

Meanwhile, the operation illustrated in FIG. 3 is performed until a voltage level of the input radio-frequency signal RFin is a certain value or less. When the voltage level of the radio-frequency signal RFin exceeds a certain value, waveforms of the voltage V1 and the voltage V2 are distorted. FIG. 4 is a diagram illustrating an example of a state in which a waveform is distorted. As illustrated in FIG. 4, when amplitudes of the voltage V1 and the voltage V2 increase, waveforms thereof are distorted. In this case, a radio-frequency amplitude appears in the detection voltage Vdet at the node between the resistor R1 and the resistor R2.

That is, when the amplitude of the radio-frequency exceeds a predetermined width, the amplitude of the radio-frequency that cannot be canceled appears, and the detection voltage Vdet increases due to the amplitude. Thereby, when a base voltage of the transistor Tr21 exceeds a threshold, the transistor Tr21 is turned on, and when the base voltage of the transistor Tr21 further increases, a part of a bias current is continuously drawn from the bias circuits B11 and B12 with higher strength than when the detection voltage Vdet is only a direct-current voltage. Thereby, even when the detection voltage Vdet itself is within a range of a normally used voltage, it is possible to reliably and durably prevent a transistor from being destroyed due to an excessively large amplitude of a radio-frequency.

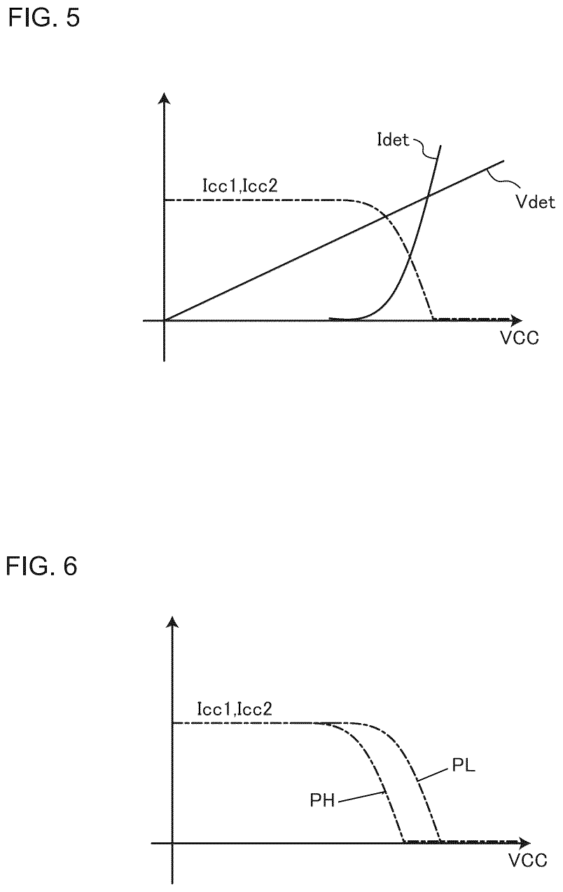

FIG. 5 is a diagram illustrating a relationship among the detection voltage Vdet outputted from the voltage detection circuit 10, the current Idet drawn by the protection circuit 30, and a collector current of each transistor. In FIG. 5, a horizontal axis denotes a voltage value of the power supply VCC, and a vertical axis denotes a voltage value or a current value.

As illustrated in FIG. 5, when the detection voltage Vdet at the node between the resistor R1 and the resistor R2 increases, the base voltage of the transistor Tr21 of the protection circuit 30 increases. When the base voltage of the transistor Tr21 increases and exceeds a certain value, the transistor Tr21 is turned on. Thereby, the current Idet, which is the drawn current, increases. When the current Idet, which is the drawn current, increases, a part of a current of each of the bias circuits B11 and B12 is drawn, and thus, a bias current can be reduced. Accordingly, a collector current Icc1 of the transistor Tr1 of the amplification unit PA1 and a collector current Icc2 of the transistor Tr2 of the amplification unit PA2 decrease.

FIG. 6 is a diagram illustrating a relationship between a voltage level of the input radio-frequency signal RFin and the collector currents Icc1 and Icc2. In FIG. 6, a horizontal axis denotes a voltage value of the power supply VCC, and a vertical axis denotes a current value. A curve PH in FIG. 6 shows a case where a voltage level of the radio-frequency signal RFin is high, and a curve PL shows a case where the voltage level of the radio-frequency signal RFin is low. As illustrated in FIG. 6, it can be seen that the collector currents Icc1 and Icc2 decrease when the voltage level of the radio-frequency signal RFin is higher than when the voltage level of the radio-frequency signal RFin is lower.

### Example of Voltage Detection Circuit

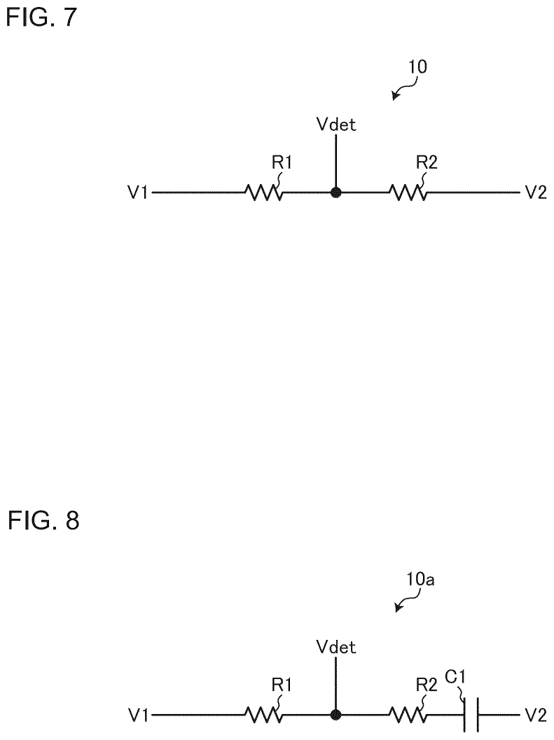

FIG. 7 is a diagram illustrating the voltage detection circuit 10 used for the power amplifier 100a illustrated in FIG. 2. The voltage detection circuit 10 illustrated in FIG. 7 includes the resistor R1 and the resistor R2 connected in series to each other. The resistor R1 corresponds to a first resistor of the present disclosure. The resistor R2 corresponds to a second resistor of the present disclosure. One end of the resistor R1 is connected to the collector of the transistor Tr1 of the amplification unit PA1. The voltage V1 of the power supply terminal VC1 is applied to one end of the resistor R1. One end of the resistor R2 is connected to the collector of the transistor Tr2 of the amplification unit PA2. The voltage V2 of the power supply terminal VC2 is applied to one end of the resistor R2. The detection voltage Vdet is obtained from the node between the other end of the resistor R1 and the other end of the resistor R2. A phase of a signal outputted from the collector of the amplification unit PA1 is different from a phase of a signal outputted from the collector of the amplification unit PA2 by about 180°. Accordingly, by combining the two signals by using the voltage detection circuit 10, amplitudes of the two signals are canceled, and the detection voltage Vdet, which is a direct-current voltage, is obtained. Resistance values of the resistor R1 and the resistor R2 are selected such that an amplitude of a radio-frequency does not appear in the detection voltage Vdet at the node between the resistor R1 and the resistor R2.

FIGS. 8 to 10 are diagrams illustrating modification examples of the voltage detection circuit 10. A voltage detection circuit 10a illustrated in FIG. 8 has a configuration in which a capacitor C1 is connected to one end of the resistor R2 of the voltage detection circuit 10 illustrated in FIG. 7. Accordingly, the resistors R1 and R2 and the capacitor C1 are configured to be connected in series to each other. The capacitor C1 is provided for direct-current cutting. The capacitor Cl corresponds to a first capacitor of the present disclosure. In the voltage detection circuit 10a illustrated in FIG. 8, resistance values of the resistor R1 and the resistor R2 and a capacitance value of the capacitor C1 are selected such that an amplitude of a radio-frequency does not appear in the detection voltage Vdet.

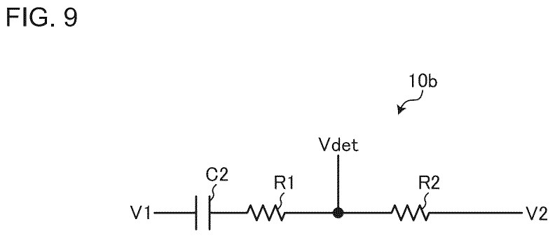

A voltage detection circuit 10b illustrated in FIG. 9 has a configuration in which a capacitor C2 is connected to one end of the resistor R1 of the voltage detection circuit 10 illustrated in FIG. 7. Accordingly, the capacitor C2, the resistor R1, and the resistor R2 are configured to be connected in series to each other. The capacitor C2 is provided for direct-current cutting. The capacitor C2 corresponds to a first capacitor of the present disclosure. In the voltage detection circuit 10b illustrated in FIG. 9, resistance values of the resistor R1 and the resistor R2 and a capacitance value of the capacitor C2 are selected such that an amplitude of a radio-frequency does not appear in the detection voltage Vdet.

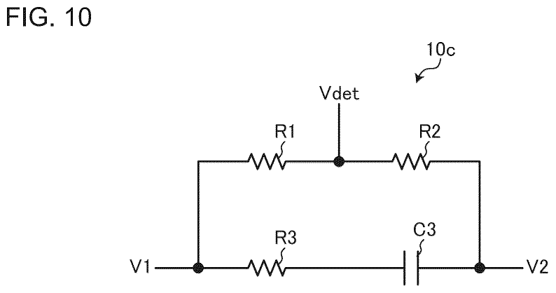

A voltage detection circuit 10c illustrated in FIG. 10 has a configuration in which a resistor R3 and a capacitor C3 are added to the voltage detection circuit 10 illustrated in FIG. 7. The resistor R3 corresponds to a third resistor of the present disclosure. The capacitor C3 is connected in series to the resistor R3. The capacitor C3 corresponds to a second capacitor of the present disclosure. The capacitor C3 is provided for direct-current cutting. The resistor R3 and the capacitor C3 are connected in parallel to the resistor R1 and the resistor R2. In the voltage detection circuit 10c illustrated in FIG. 9, resistance values of the resistor R1, the resistor R2, and the resistor R3 and a capacitance value of the capacitor C3 are selected such that an amplitude of a radio-frequency does not appear in the detection voltage Vdet.

### Example of Level Shift Circuit and Protection Circuit

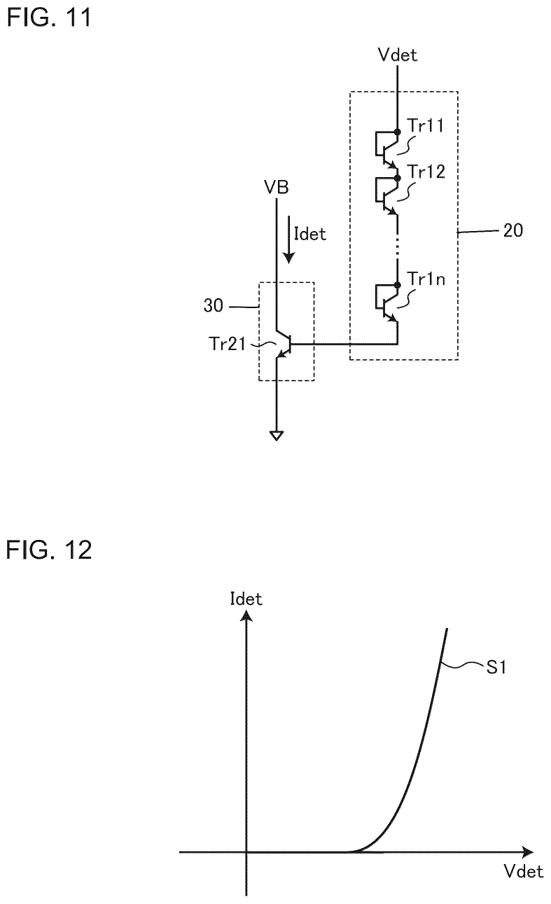

FIG. 11 is a diagram illustrating a first example of the level shift circuit 20 and the protection circuit 30 used for the power amplifier 100a illustrated in FIG. 2. FIG. 12 is a waveform diagram illustrating operations of the level shift circuit 20 and the protection circuit 30 illustrated in FIG. 11.

As described above, the level shift circuit 20 includes n transistors Tr11, Tr12, . . . , and Tr1n. A detection voltage Vdet, which is outputted from the voltage detection circuit 10, is applied to a collector and a base of the transistor Tr11. The detection voltage Vdet is applied to a base of the transistor Tr21 of the protection circuit 30 after a voltage level is converted by the level shift circuit 20. When the transistor Tr21 is turned on, a current Idet flows as indicated by a curve S1 in FIG. 12. When the current Idet flows, a power supply voltage VB for the bias circuits B11 and B12 is reduced. That is, the current Idet is a drawn current for the power supply voltage VB. The protection circuit 30 reduces base bias currents applied to the transistors Tr1 and Tr2 based on a voltage of which level is converted by the level shift circuit 20. That is, when the transistor Tr21 which is the third transistor is turned on, the bias current applied to the transistor Tr1 from the bias circuit B11 and the bias current applied to the transistor Tr2 from the bias circuit B12 are reduced.

In FIG. 12, a horizontal axis denotes the detection voltage Vdet, and a vertical axis denotes the current Idet. When a voltage applied to the base of the transistor Tr21 of the protection circuit 30 exceeds a predetermined threshold, the transistor Tr21 is turned on. When the transistor Tr21 is turned on, the current Idet flows, and when the detection voltage Vdet increases, the current Idet which is a drawn current increases.

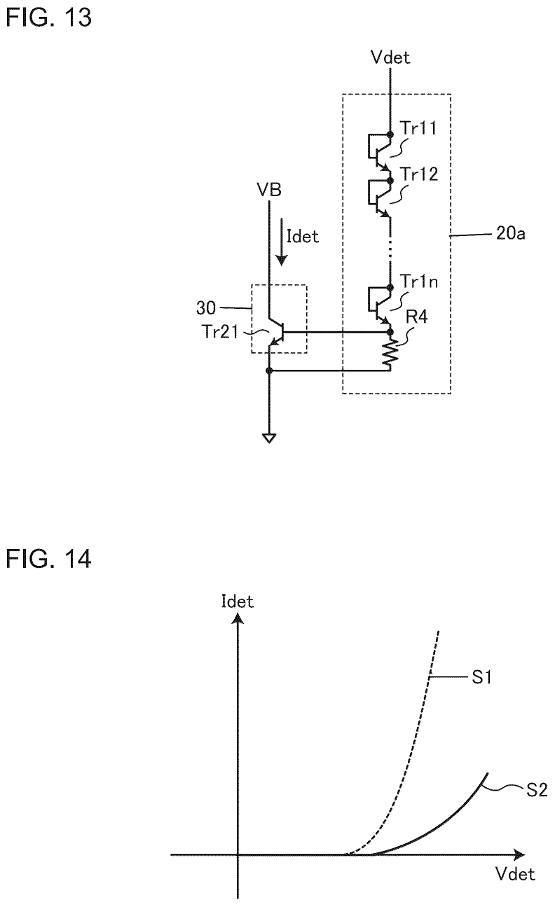

FIG. 13 is a diagram illustrating a second example of the level shift circuit and the protection circuit. A level shift circuit 20a illustrated in FIG. 13 has a configuration in which a resistor R4 is added to the level shift circuit 20 illustrated in FIG. 11. One end of the resistor R4 is connected to an emitter of a transistor Tr1n. The other end of the resistor R4 is connected to a reference voltage. Accordingly, a detection voltage Vdet is resistance-divided by the level shift circuit including n transistors Tr11, Tr12, . . . , and Tr1n and the resistor R4. A voltage obtained by the resistance division is applied to the base of the transistor Tr21 of the protection circuit 30. The resistor R4 corresponds to a fourth resistor of the present disclosure.

FIG. 14 is a waveform diagram illustrating operations of the level shift circuit 20a and the protection circuit 30 illustrated in FIG. 13. As described above, the voltage obtained by the resistance division is applied to the base of the transistor Tr21 of the protection circuit 30. Accordingly, in the present example, a current Idet gradually increases as indicated by curve S2, compared with the current Idet in FIG. 12 indicated by a curve of a dashed line S1 in FIG. 14. Therefore, in the level shift circuit 20a and the protection circuit 30 illustrated in FIG. 13, a rapid increase of the current Idet, which is a drawn current, can be suppressed by adding the resistor R4.

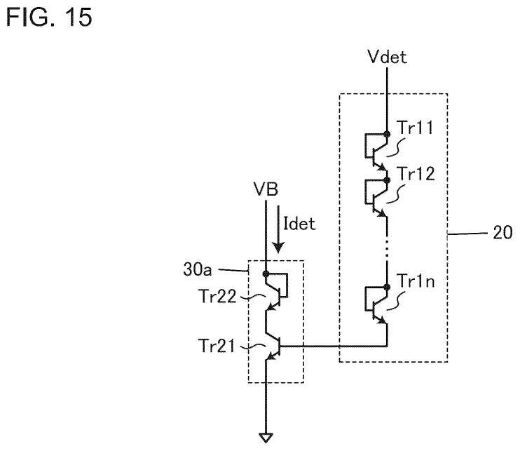

FIG. 15 is a diagram illustrating a third example of the level shift circuit and the protection circuit. In the protection circuit 30 in FIG. 11, when the power supply voltage VB decreases to be, for example, 0 V, it is assumed that the transistor Tr21 is turned on in a reverse direction and a current flows from the base of the transistor Tr21 to a collector of the transistor Tr21. That is, it is also assumed that the current Idet flows in the reverse direction.

In order to prevent the current Idet from flowing in the reverse direction, that is, to prevent the current from flowing reversely, the transistor Tr22 is added to a protection circuit 30a in FIG. 15. Since a base and a collector of the transistor Tr22 are connected to each other, the transistor Tr22 operates as a diode. Therefore, it is possible to prevent the current Idet from flowing in the reverse direction. The transistor Tr22 corresponds to a reverse flow prevention element of the present disclosure.

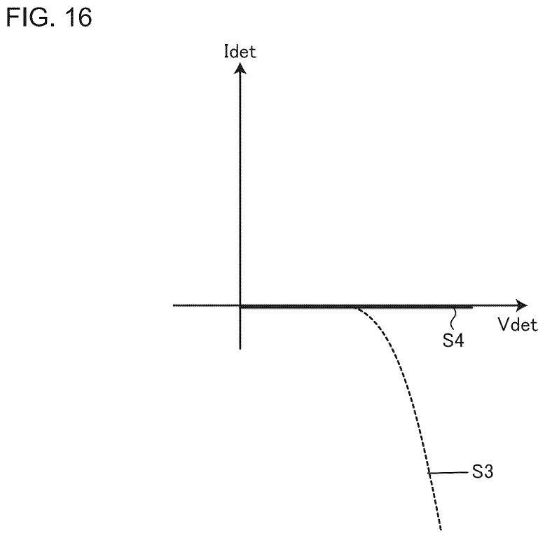

FIG. 16 is a waveform diagram illustrating operations of the level shift circuit 20 and the protection circuit 30a illustrated in FIG. 15. When the transistor Tr21 is turned on in the reverse direction, the current Idet flows in the reverse direction as indicated by a curve of a dashed line S3 in FIG. 16. By adding a transistor Tr22 that operates as a diode as illustrated in FIG. 15, a current does not flow in the reverse direction as illustrated by a solid line S4 in FIG. 16 even when the detection voltage Vdet increases.

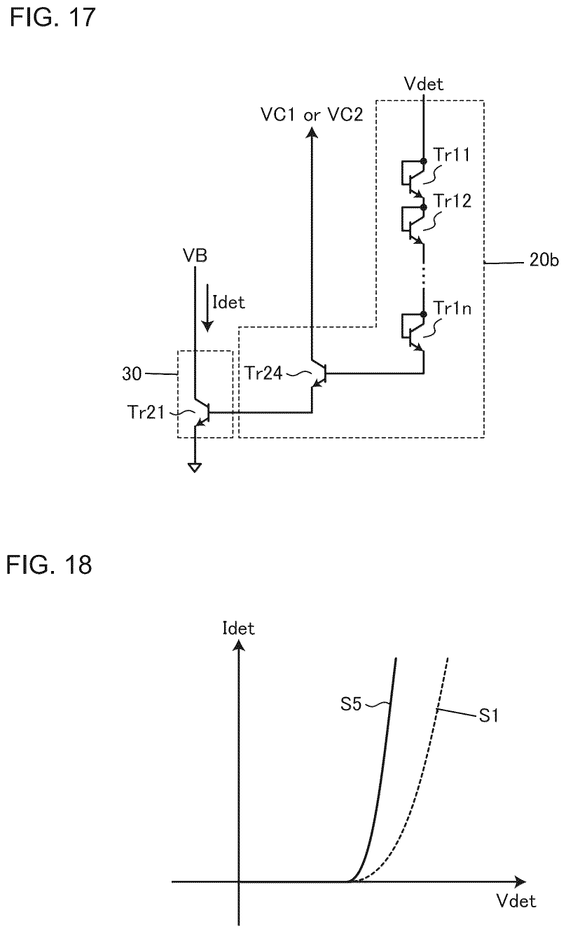

FIG. 17 is a diagram illustrating a fourth example of the level shift circuit and the protection circuit. In FIG. 17, a level shift circuit 20b in which a transistor Tr24 is added to the level shift circuit 20 in FIG. 11 is adopted. The transistor Tr24 is provided between the transistor Tr1n and the transistor Tr21. The transistor Tr24 is turned on by a voltage of which level is converted by the level shift circuit. The transistor Tr24 corresponds to a fourth transistor of the present disclosure.

For the detection voltage Vdet, a resistor may be inserted between the node of the resistor R1 and the resistor R2 (refer to FIG. 2) and the level shift circuit 20. In this case, it is also assumed that a base voltage for turning on the transistor Tr21 of the protection circuit 30 is not sufficient. Therefore, the transistor Tr24 that is Darlington-connected to the transistor Tr21 is added. A collector of the transistor Tr24 is connected to the power supply terminal VC1 or VC2, and the power supply VCC is applied to the collector of the transistor Tr24.

FIG. 18 is a waveform diagram illustrating operations of the level shift circuit 20b and the protection circuit 30 illustrated in FIG. 17. A curve of a dashed line S1 in FIG. 18 corresponds to the current Idet in FIG. 12. By adding the transistor Tr24, the current Idet can rapidly increase as indicated by a curve of a solid line S5 in FIG. 18. Therefore, by adding the transistor Tr24, the speed of drawing a current can be increased.

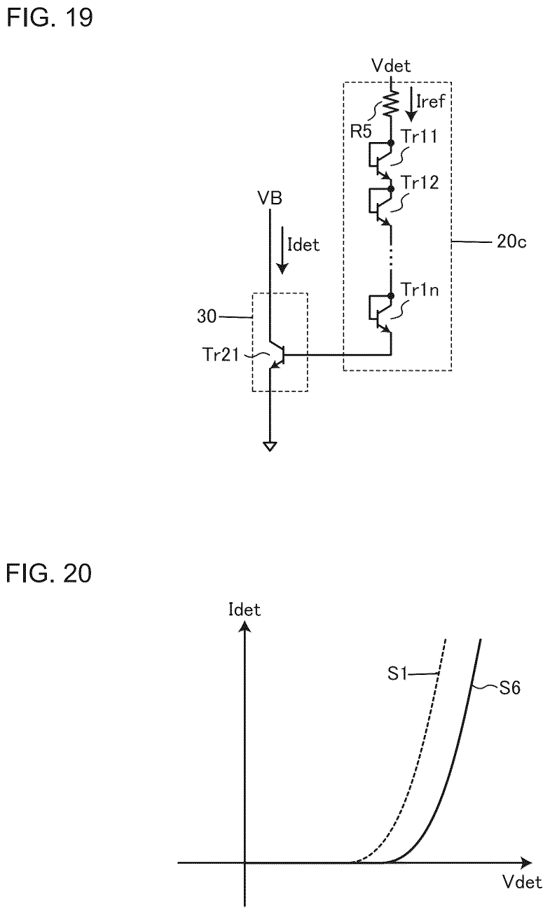

FIG. 19 is a diagram illustrating a fifth example of the level shift circuit and the protection circuit. In FIG. 19, a resistor R5 is inserted between the node of the resistor R1 and the resistor R2 (see FIG. 2) and a diode circuit. An operation point of a transistor Tr21 of the protection circuit 30 can be adjusted by product of a resistance value of the resistor R5 and the current Iref flowing through the resistor R5, and the entire curve of the current Idet can be shifted.

FIG. 20 is a waveform diagram illustrating operations of a level shift circuit 20c and the protection circuit 30 illustrated in FIG. 19. A curve of a dashed line S1 in FIG. 20 corresponds to the current Idet in FIG. 12. By adding the resistor R5, the entire current Idet can be shifted as indicated by a curve of a solid line S6 in FIG. 20.

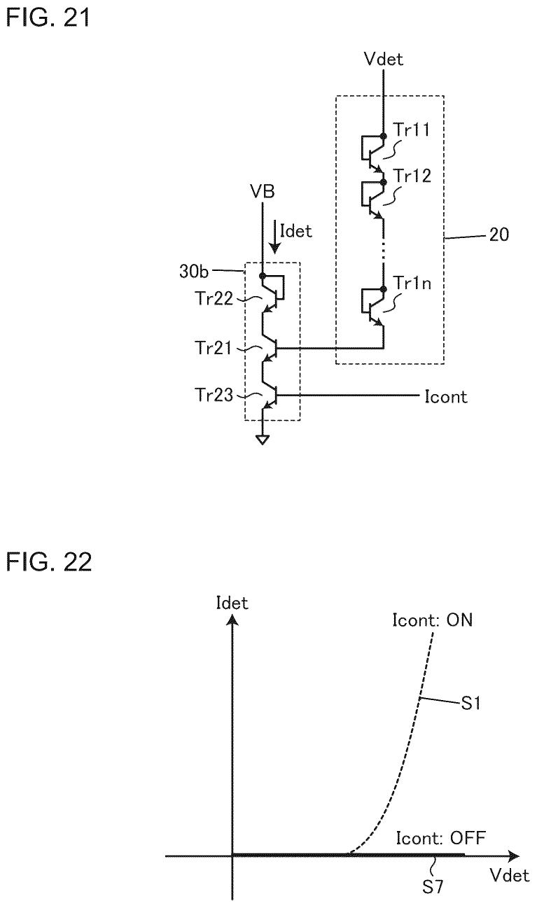

FIG. 21 is a diagram illustrating a sixth example of the level shift circuit and the protection circuit. In FIG. 21, a protection circuit 30b in which a transistor Tr23 is added to the protection circuit 30a in FIG. 15 is adopted. The transistor Tr23 is provided on a reference potential side of the transistor Tr21. The transistor Tr23 corresponds to a fifth transistor of the present disclosure.

A control current Icont is applied to a base of the transistor Tr23. The control current Icont corresponds to a predetermined control signal of the present disclosure. As will be described below, an operation of drawing the current Idet can be performed or stopped by applying the control current Icont according to an operation mode of a power amplifier.

FIG. 22 is a waveform diagram illustrating operations of the level shift circuit 20c and the protection circuit 30 illustrated in FIG. 21. A curve of a dashed line S1 in FIG. 22 corresponds to the current Idet in FIG. 12. By turning on the transistor Tr23 and performing an operation of drawing the current Idet, the current Idet increases according to an increase in the detection voltage Vdet as indicated by a dashed line in FIG. 22. Meanwhile, by turning off the transistor Tr23 and stopping the operation of drawing the current Idet, the current Idet does not increase as indicated by a solid line S7 in FIG. 22 even when the detection voltage Vdet increases. As described above, the operation of drawing the current Idet can be performed or stopped by the control current Icont applied according to an operation mode of the power amplifier.

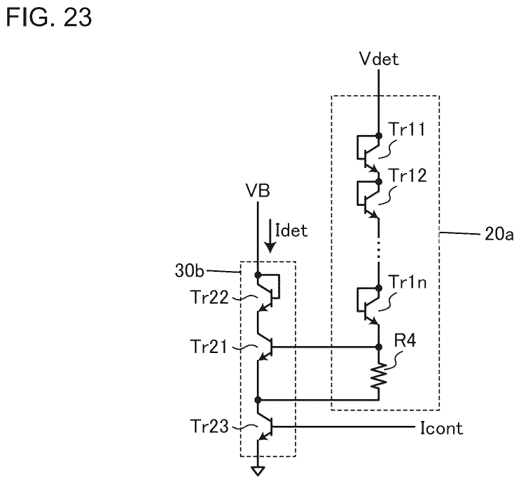

Meanwhile, configurations of the level shift circuit and the protection circuit described with reference to FIGS. 11 to 22 can be combined with each other. FIG. 23 is a diagram illustrating a first example in which a level shift circuit is combined with a protection circuit. A first example illustrated in FIG. 23 is an example in which the level shift circuit 20a described with reference to FIG. 13 is combined with the protection circuit 30b described with reference to FIG. 21. With the configuration of the first example illustrated in FIG. 23, the current Idet can be prevented from flowing in the reverse direction, and the operation of drawing the current Idet can be performed or stopped.

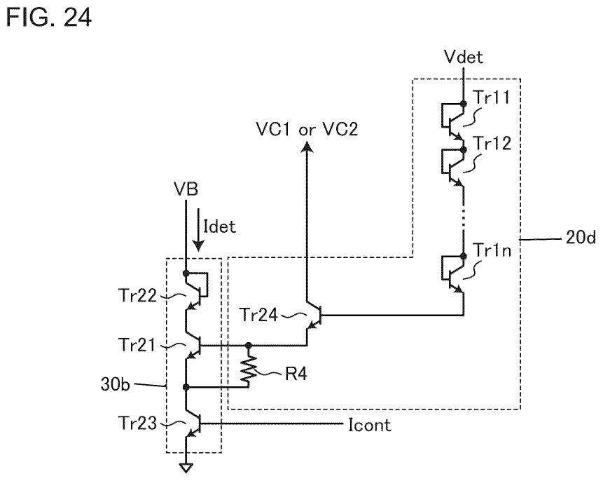

FIG. 24 is a diagram illustrating a second example in which a level shift circuit is combined with a protection circuit. The second example illustrated in FIG. 24 is an example in which the protection circuit 30b described with reference to FIG. 21 is combined with the level shift circuit 20a described with reference to FIG. 13 and the transistor Tr24 described with reference to FIG. 17 added to the level shift circuit 20a. With the configuration of the second example illustrated in FIG. 24, the current Idet can be prevented from flowing in the reverse direction, the operation of drawing the current Idet can be performed or stopped, and the speed of drawing a current can be further increased.

### Effects

With the power amplifier 100a of the first embodiment, a transistor included in an amplification unit can be prevented from being destroyed. In addition, when the detection voltage Vdet exceeds a predetermined voltage, a current is continuously drawn, and thus, a protection state continues, and the protection from destruction can be performed more reliably.

### Second Embodiment

### Configuration

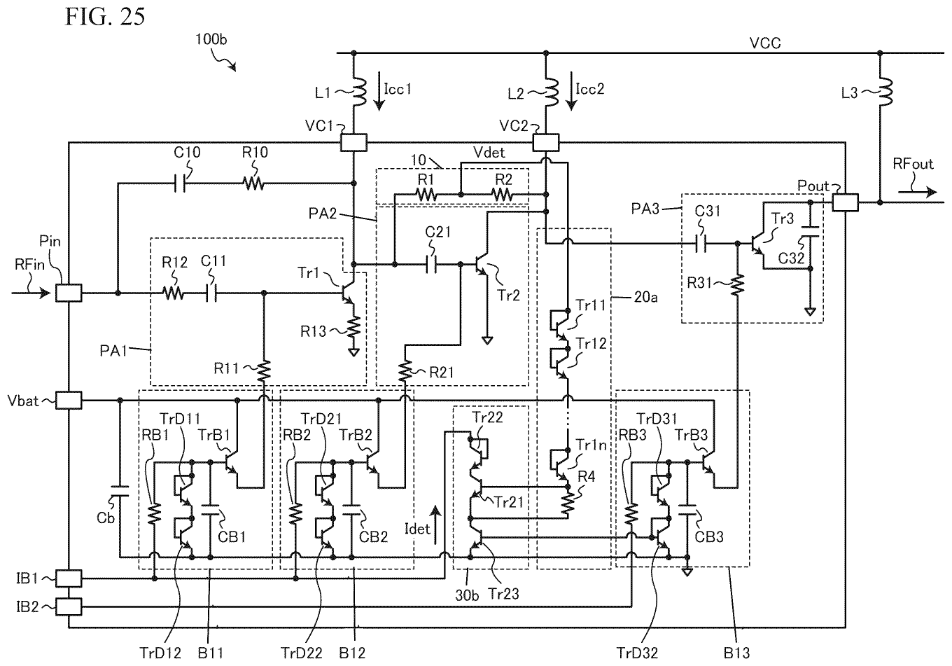

FIG. 25 is a diagram illustrating a power amplifier 100b according to a second embodiment of the present disclosure. In FIG. 25, the power amplifier 100b according to the second embodiment has a configuration in which the level shift circuit 20a described with reference to FIG. 13 and the protection circuit 30b described with reference to FIG. 21 are adopted in the power amplifier 100a according to the first embodiment.

In FIG. 25, the power amplifier 100b according to the second embodiment includes amplification units PA1, PA2, and PA3 and bias circuits B11, B12, and B13 respectively corresponding to the amplification units PA1, PA2, and PA3, in the same manner as the power amplifier 100a according to the first embodiment. The bias circuits B11, B12, and B13 have the same configurations as the bias circuits B11 and B12 of the power amplifier 100a. However, a base of a transistor TrD32 of the bias circuit B13 is connected to a base of a transistor Tr23 of a protection circuit 30b. Thereby, a current mirror circuit is formed by the transistor TrD32 and the transistor Tr23.

### Operation

When a control voltage applied to a bias input terminal IB2 exceeds a predetermined value, the transistor Tr23 is turned on, and the protection circuit 30b operates. Thereby, in the same manner as the power amplifier 100a according to the first embodiment, a current is drawn according to the detection voltage Vdet, and each of transistors Tr1 and Tr2 is protected. When the voltage applied to the bias input terminal IB2 is less than the predetermined value, the transistor Tr23 is turned off, and the protection circuit 30b does not operate.

### Effects

A state for protecting each of the transistors Tr1 and Tr2 can be set to on or off according to a control voltage applied to the bias input terminal IB2.

### Third Embodiment

### Configuration

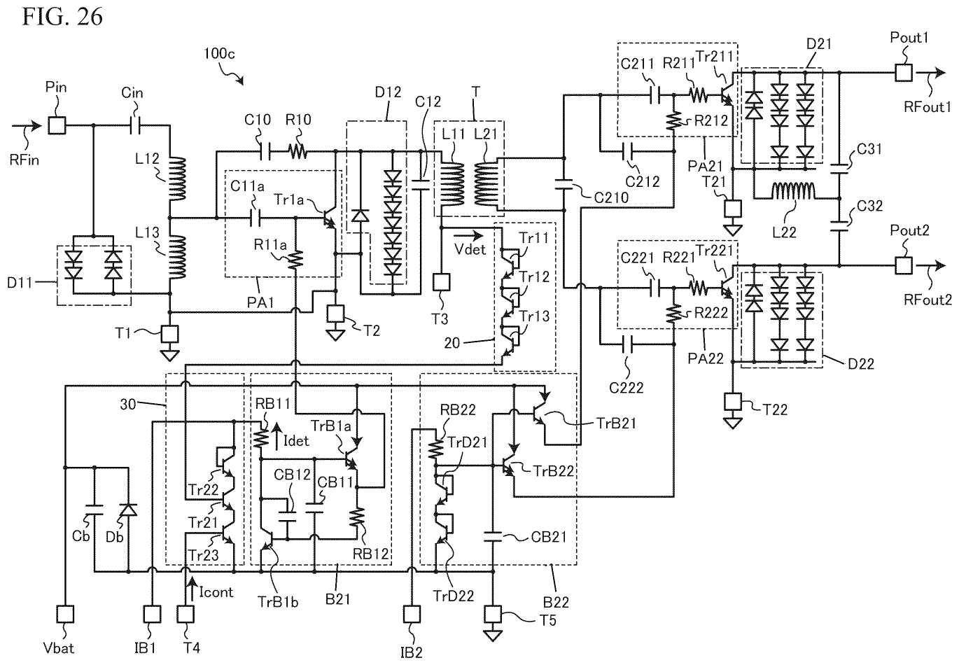

FIG. 26 is a diagram illustrating a power amplifier 100c according to a third embodiment of the present disclosure. The power amplifier 100c according to the third embodiment can handle the amplification operations of two different wireless communication methods. The power amplifier 100c performs, for example, an amplification operation (hereinafter, referred to as a 2nd generation (2G) mode) corresponding to a wireless communication of 2G and an amplification operation (hereinafter, referred to as a 5th generation (5G) mode) corresponding to a wireless communication system of 5G.

In FIG. 26, the power amplifier 100c according to the third embodiment includes an amplification unit PA1 at an initial stage, and amplification units PA21 and PA22 at a second stage. An output of the amplification unit PA1 is inputted to the amplification units PA21 and PA22. The amplification units PA21 and PA22 form a pair of differential amplification units.

A capacitor Cin, an inductor L12 and an inductor L13 which are connected in series to each other, and a diode unit D11 are provided between an input terminal Pin and the amplification unit PA1.

The amplification unit PA1 includes a transistor Tr1a having multiple fingers, a capacitor C11a connected to a collector of the transistor Tr1a, and a resistor R11a. The transistor Tr1a is a common-emitter and forms an amplification circuit.

A diode unit D12, a capacitor C12, and a balun T are provided between the amplification unit PA1 and the amplification units PA21 and PA22. A balun T is realized by a transformer including primary winding L11 and secondary winding L21. The primary winding L11 and the secondary winding L21 are electromagnetically coupled to each other. One end of the primary winding L11 of the balun T is connected to a collector of the amplification unit PA1. The other end of the primary winding L11 is connected to a terminal T3. The primary winding L11 corresponds to an impedance element of the voltage detection circuit according to the embodiment of the present disclosure. A direct-current voltage is outputted by using the primary winding L11 that is an impedance element.

An amplification output of the amplification unit PA21 is applied to one end of the secondary winding L21 of the balun T. The amplification unit PA22 is connected to the other end of the secondary winding L21. A capacitor C210 is provided between both ends of the secondary winding L21.

The other end of the primary winding L11 of the balun T is connected to a level shift circuit 20. The level shift circuit 20 includes transistors Tr11, Tr12, and Tr13 that operate as diodes. The level shift circuit 20 is connected to a protection circuit 30b. A configuration of the protection circuit 30b is as described with reference to FIG. 21.

The amplification unit PA21 includes a transistor Tr211 having multiple fingers, a capacitor C211 connected to a collector of the transistor Tr211, and a resistor R212. The transistor Tr211 is a common-emitter and forms an amplification circuit. A capacitor C212 is connected between one end of the capacitor C211 and one end of the resistor R212.

The amplification unit PA22 includes a transistor Tr221 having multiple fingers, a capacitor C221 connected to a collector of the transistor Tr221, and a resistor R222. The transistor Tr221 is a common-emitter and forms an amplification circuit. A capacitor C222 is connected between one end of the capacitor C221 and one end of the resistor R222.

A diode unit D21 is provided between the amplification unit PA21 and an output terminal Pout1. A diode unit D22 is provided between the amplification unit PA22 and an output terminal Pout2. A capacitor C31 and a capacitor C32 connected in series to each other, and an inductor L22 are provided between the amplification units PA21 and PA22 and the output terminals Pout1 and Pout2. One end of the inductor L22 is connected to a node between the capacitor C31 and the capacitor C32. The other end of the inductor L22 is connected to an emitter of the transistor Tr211.

A bias circuit B21 is provided to correspond to the amplification unit PA1. The bias circuit B21 includes a transistor TrB1a having multiple fingers, a transistor TrB1b, a capacitor CB11 connected between a base of the transistor TrB1a and a reference potential, a capacitor CB12 connected between a collector and a base of the transistor TrB1b, a resistor RB11, and a resistor RB12. A bias current is supplied to the amplification unit PA1 by turning on the transistor TrB1a. A capacitor Cb and a diode Db are connected between a power supply terminal Vbat of each of the bias circuits B21 and B22 and the reference potential.

The bias circuit B22 is provided to correspond to the amplification units PA21 and PA22. The bias circuit B22 includes a transistor TrB21 and a transistor TrB22 having multiple fingers, a capacitor CB21 connected between bases of the transistors TrB21 and TrB22 and the reference potential, transistors TrD21 and TrD22 that operate as diodes, and a resistor RB22. A bias current is supplied to the amplification unit PA21 by turning on the transistor TrB21. The bias current is supplied to the amplification unit PA22 by turning on the transistor TrB22.

A terminal T1, a terminal T2, a terminal T5, a terminal T21, and a terminal T22 are connected to the reference potential. A power supply voltage is applied to the terminal T3. By applying the power supply voltage to the terminal T3, a direct-current voltage appearing in the primary winding L11 is inputted to the level shift circuit 20 as the detection voltage Vdet. A control current Icont is applied to the terminal T4. By turning on or off the transistor Tr23 of the protection circuit 30 according to the control current Icont, an operation (hereinafter, referred to as a current drawing operation) of drawing a current of the protection circuit 30 can be set to an on-state or an off-state.

### Operation

In the power amplifier 100c, the wireless communication in the 2G mode and the wireless communication in the 5G mode have different magnitudes in output power. Specifically, in the 2G mode and the 5G mode, an amplitude of the radio-frequency signal RFout1 outputted from a collector of the transistor Tr211 of the amplification unit PA21 is different from an amplitude of the radio-frequency signal RFout2 outputted from a collector of the transistor Tr221 of the amplification unit PA22.

In addition, a power supply voltage applied to the terminal T3 is different between the 2G mode and the 5G mode. In the 2G mode, a current drawing operation is performed by providing the control current Icont. Meanwhile, when the power supply voltage applied to the terminal T3 is high in the 5G mode, the detection voltage Vdet increases, and the current drawing operation is performed. Therefore, in the 5G mode, the control current Icont is set to, for example, 0 amperes. Thereby, the transistor Tr23 is turned off, and accordingly, the current drawing operation is set to be stopped, and it is possible to prevent the current drawing operation from being performed.

### Effects

In the 2G mode in which destruction test conditions are severe, a predetermined control current Icont which is not 0 amperes is applied to operate the protection circuit 30. With this configuration, the current Idet flows, a current is drawn, an output power level of the amplification unit PA1 is reduced, and thereby, the power transmitted from the primary winding L11 side of the balun T to the secondary winding L21 side of the balun T is reduced. Thereby, it is possible to prevent the transistor Tr211 of the amplification unit PA21 and the transistor Tr221 of the amplification unit PA22 from being destroyed. Meanwhile, in the 5G mode, by setting the control current Icont to 0 amperes, the current drawing operation can be prevented from being performed.

### Example of Layout of Power Amplifier

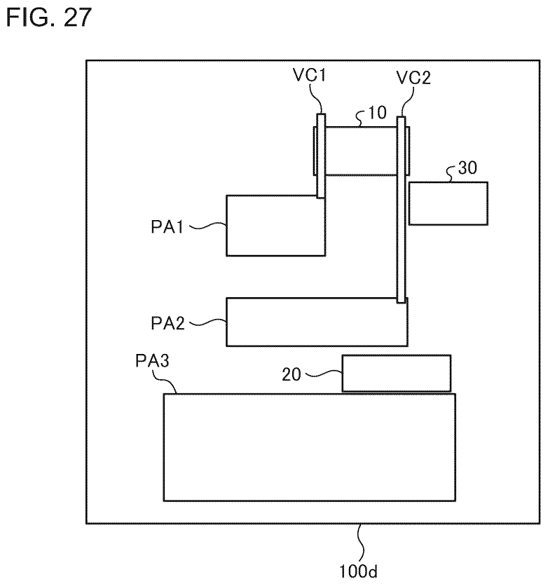

FIGS. 27 to 29 are diagrams illustrating examples of layouts when the power amplifier of the present disclosure is implemented on a substrate. FIGS. 27 to 29 schematically illustrate layouts when the power amplifier is implemented on a substrate.

In FIG. 27, a power amplifier 100d includes an amplification unit PA1, an amplification unit PA2, an amplification unit PA3, a voltage detection circuit 10, a level shift circuit 20, a protection circuit 30, and power supply wires VC1 and VC2 that supply power supply voltages applied to power supply terminals. The same reference numerals “VC1” and “VC2” are respectively added to the power supply wires for supplying power supply voltages applied to the power supply terminals VC1 and VC2.

The amplification unit PA1 is an amplification unit at a first stage, that is, an initial stage. The amplification unit PA2 is an amplification unit at a second stage, that is, an intermediate stage. The amplification unit PA3 is an amplification unit at a third stage, that is, a last stage. The amplification unit PA3 at the last stage has a larger amount of heat generation than the amplification units PA1 and PA2. Therefore, in the power amplifier 100d, the level shift circuit 20 is provided in the vicinity of the third amplification unit PA3 as illustrated in FIG. 27. By laying out the respective units in this way, it is expected that the level shift circuit 20 is thermally coupled to the third amplification unit PA3. As the level shift circuit 20 is thermally coupled to the third amplification unit PA3, a threshold of a transistor in the level shift circuit 20 can be reduced when an input power level is increased.

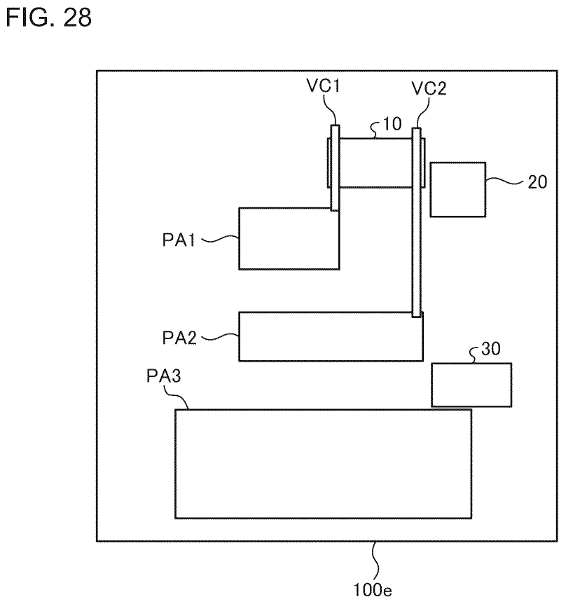

In FIG. 28, in a power amplifier 100e, a protection circuit 30 is provided in the vicinity of the third amplification unit PA3, unlike the power amplifier 100d described with reference to FIG. 27. By laying out the respective units in this way, the protection circuit 30 can be expected to be thermally coupled to the third amplification unit PA3. As the protection circuit 30 is thermally coupled to the third amplification unit PA3, the protection circuit 30 can start to operate at a lower power supply voltage than when an output power of the power amplifier 100e is low.

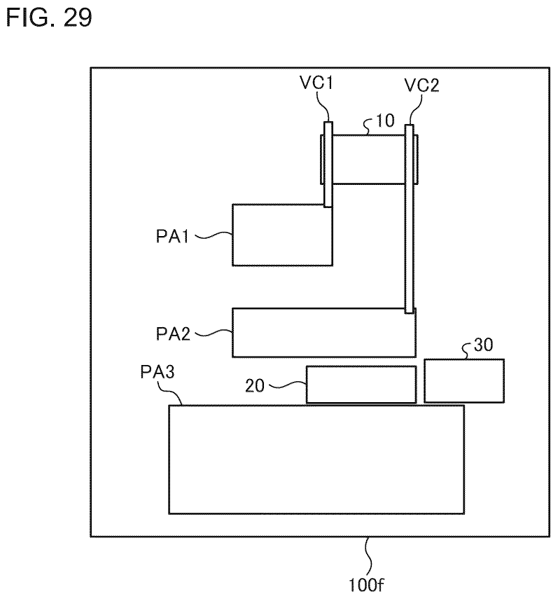

In FIG. 29, in a power amplifier 100f, a level shift circuit 20 and a protection circuit 30 are provided in the vicinity of the third amplification unit PA3. By laying out the respective units in this way, it can be expected that the level shift circuit 20 and the protection circuit 30 are thermally coupled to the third amplification unit PA3. As the level shift circuit 20 and the protection circuit 30 are thermally coupled to the third amplification unit PA3, a threshold of a transistor in the level shift circuit 20 can be reduced, and the protection circuit 30 can start an operation at a lower power supply voltage than when the output power of the power amplifier 100e is low.

What is claimed is:

1. A power amplifier comprising:
a plurality of stages of unit amplifiers, each of which comprises a common-emitter transistor;
a first unit amplifier comprising a first transistor configured to amplify an input radio-frequency signal;
a second unit amplifier comprising a second transistor configured to amplify an output of the first unit amplifier;
a voltage detection circuit between the first transistor and the second transistor, and comprising at least one impedance circuit element; and
a protection circuit configured to reduce a base bias current applied to the first transistor or the second transistor, based on an output of the voltage detection circuit.

2. The power amplifier according to claim 1,
wherein the impedance circuit element comprises, a first resistor and a second resistor,
wherein the second resistor is connected to the first resistor, and
wherein a detection voltage is output from a node between the first resistor and the second resistor.

3. The power amplifier according to claim 2,
wherein the first resistor is electrically connected to a collector of the first transistor, and
wherein the second resistor is electrically connected to a collector of the second transistor.

4. The power amplifier according to claim 3, wherein the impedance circuit element further comprises a first capacitor connected in series to the first resistor or the second resistor.

5. The power amplifier according to claim 2,
wherein the first resistor is electrically connected to a collector of the first transistor,
wherein the second resistor is electrically connected to a collector of the second transistor,
wherein the impedance circuit element further comprises a third resistor electrically connected to the collector of the first transistor and a second capacitor connected in series to the third resistor, and
wherein the third resistor and the second capacitor are connected in parallel to the first resistor and the second resistor.

6. The power amplifier according to claim 1 further comprising:
a first bias circuit configured to apply a first bias current to the first transistor; and
a second bias circuit configured to apply a second bias current to the second transistor,
wherein the protection circuit comprises a third transistor that is configured to turn on based on the output of the voltage detection circuit, and
wherein when the third transistor is on, the protection circuit is configured to reduce the first bias current applied from the first bias circuit to the first transistor, and the second bias current applied from the second bias circuit to the second transistor.

7. The power amplifier according to claim 6, further comprising:
a level shift circuit configured to convert a level of a voltage output from the voltage detection circuit,
wherein the level shift circuit comprises a diode circuit including at least one diode, and
wherein the protection circuit is configured to reduce the first bias current applied to the first transistor and the second bias applied to the second transistor based on a voltage of which level is converted by the level shift circuit.

8. The power amplifier according to claim 7,
wherein the level shift circuit further comprises a fourth resistor connected in series to the diode circuit, and
wherein the third transistor is configured to turn on by a voltage divided by the diode circuit and the fourth resistor.

9. The power amplifier according to claim 8,
wherein the level shift circuit further comprises a fourth transistor that is configured to turn on by a voltage having a level that is converted by the diode circuit, and
wherein a predetermined power supply voltage is input to a base of the third transistor in an on-state of the fourth transistor.

10. The power amplifier according to claim 7, further comprising:
a reverse flow prevention circuit element configured to prevent a reverse flow of a current from the third transistor to the first bias circuit and the second bias circuit.

11. The power amplifier according to claim 7,
wherein the protection circuit further comprises a fifth transistor that is configured to operate by a predetermined control signal, and
wherein when the fifth transistor is in an on-state, the third transistor is configured to turn on, and the bias current applied to the first transistor and the second transistor is reduced.

12. The power amplifier according to claim 7, wherein the level shift circuit further comprises a fifth resistor connected in series between the voltage detection circuit and the diode circuit of the level shift circuit.

13. The power amplifier according to claim 1, further comprising:
a balun having primary winding and secondary winding,
wherein the primary winding is electrically connected to the first amplification unit,
wherein the secondary winding is electrically connected to the second amplification unit, and
wherein the voltage detection circuit is configured to use the primary winding as the impedance element and obtain the detection voltage using the primary winding.

14. The power amplifier according to claim 13, wherein the second unit amplifier comprises a pair of differential unit amplifiers electrically connected to the secondary winding.

15. The power amplifier according to claim 7, further comprising:
a third unit amplifier configured to operate as a power stage for amplifying an output of the second unit amplifier,
wherein the first unit amplifier, the second unit amplifier, the third unit amplifier, the voltage detection circuit, the protection circuit, and the level shift circuit are formed on one substrate, and
wherein the protection circuit or the level shift circuit is adjacent to the third amplification unit in the substrate.

16. The power amplifier according to claim 2, further comprising:
a first bias circuit configured to apply a first bias current to the first transistor; and
a second bias circuit configured to apply a second bias current to the second transistor,
wherein the protection circuit comprises a third transistor that is configured to turn on based on the output of the voltage detection circuit, and
wherein when the third transistor is on, the protection circuit is configured to reduce the first bias current applied from the first bias circuit to the first transistor and the second bias current applied from the second bias circuit to the second transistor.
